(19) United States
(12) Patent Application Publication
(10) Pub. No.: US 2024/0062989 A1
(43) Pub. Date: Feb. 22, 2024

(54) DEVICE FOR IMAGING AND PROCESSING A SAMPLE USING A FOCUSED PARTICLE BEAM

(71) Applicants: Carl Zeiss SMT GmbH, Oberkochen (DE); Carl Zeiss Microscopy GmbH, Jena (DE)

(72) Inventors: Daniel Schwarz, Aalen (DE); David Laemmle, Darmstadt (DE); Michael Schnell, Rechberghausen (DE); Thomas Beck, Karlsruhe (DE); Florian Neuberger, Hanau (DE)

(21) Appl. No.: 18/235,097

(22) Filed: Aug. 17, 2023

(30) Foreign Application Priority Data
Aug. 18, 2022 (DE) 102022208597.3

(51) Int. Cl. H01J 37/28; H01J 37/305; H01J 37/18

(52) U.S. Cl. CPC H01J 37/28; H01J 37/3056; H01J 37/18; H01J 2237/006; H01J 2237/31744

(57) ABSTRACT

The present application relates to a device for imaging and processing a sample using a focused particle beam, comprising: (a) at least one particle source which is configured to create a particle beam in an ultrahigh vacuum environment; (b) at least one sample chamber which serves to accommodate the sample and which is configured to image the sample in a high vacuum environment and process the sample in a medium vacuum environment; (c) at least one column which is arranged in a high vacuum environment and which has at least one particle-optical component configured to shape a focused particle beam from the particle beam and direct said focused particle beam at the sample; (d) at least one detection unit which is arranged within the at least one column and which is configured to detect particles emanating from the sample; (e) at least one gas line system which terminates at the outlet of the focused particle beam from the column and which is configured to locally provide at least one process gas at the sample with a pressure such that the focused particle beam is able to induce a particle beam-induced local chemical reaction for processing the sample; and (f) at least one pressure adjustment unit through which the particle beam and the particles emanating from the sample pass and which is configured to limit a pressure increase caused at the at least one detection unit as a result of processing the sample to a factor of 10 or less, preferably to a factor of 5 or less, more preferably to a factor of 3 or less, and most preferably to a factor of 2 or less, without impeding access of the particles emanating from the sample to the at least one detection unit.

### CROSS-REFERENCE TO RELATED APPLICATION

The present patent application claims the priority of the German patent application DE 10 2022 208 597.3, entitled “Vorrichtung zum Abbilden und Bearbeiten einer Probe mit einem fokussierten Teilchenstrahl,” which was filed with the German Patent and Trademark Office on Aug. 18, 2022. The German patent application DE 10 2022 208 597.3 is incorporated by reference in its entirety in the present application.

### TECHNICAL FIELD

The present invention relates to a device for imaging and processing a sample using a focused particle beam, in particular an electron beam.

### BACKGROUND

Advances in nanotechnology make it possible to produce components with structure elements becoming smaller and smaller. The display and processing of the chip structures of microscopic or nanoscopic components requires tools which are able to image and modify these chip structures.

Microscopes are potent tools for imaging nanostructures. In microscopes, a particle beam typically interacts with a sample to be analyzed and/or processed. Microscopes that use particles with mass, for example electrons, to scan a sample have a high diffraction-limited resolution when imaging a nanostructure by way of scanning the particle beam over the sample, on account of the short de Broglie wavelength of the particles in the particle beam thereof. By way of example, electron beams can currently be focused on diameters in the single-digit nanometer range.

Scanning electron microscopes typically operate in vacuo, which is to say under high vacuum (HV) conditions, so that the electron beam thereof is not scattered on account of interaction with molecules on the path from the electron source to the incidence on a sample and fanned open as a result. The production of electrons for an electron beam, for instance as a result of field emission at a Schottky cathode, is implemented in an ultrahigh vacuum (UHV) environment.

Scanning electron microscopes (SEM) or ion beam (FIB) microscopes or particle beam microscopes in general can be modified such that these can be used not only to image samples but also to locally process the latter. To this end, a process gas or a precursor gas is applied to the sample and activated with the aid of the focused particle beam such that there is a local etching or deposition reaction. A minimum amount or a local minimum concentration of precursor gas particles is required at the sample surface so that the focused particle beam can initiate and maintain a local chemical reaction. Typically—depending on the process gas used—the reaction speed increases with an increase in the local gas concentration at the reaction location, and so a local concentration of process gas that is as high as possible is desirable.

However, the introduction of a process gas into an SEM or FIB microscope undermines its HV environment. Some of the difficulties arising as a result are briefly touched on below.

A portion of the process gas and/or its reaction products may penetrate into the optical or particle-optical system, which is also referred to hereinbelow as particle beam column or abbreviated as column, and may cause temporary or permanent damage there to different components, for example the particle beam source and/or the particle detector or detectors. An SEM has a particle beam column in the form of an electron beam column, abbreviated as column.

The focused particle beam is scattered at the particles of the process gas and/or its reaction products. As a result, the particle beam is fanned open (“beam skirt”) and there is a reduction in the lateral spatial resolution of the local chemical reaction. Moreover, the resultant beam skirt makes control of the local chemical reaction more difficult.

Moreover, gas discharges at locations where high electric field strengths are present, for instance in an electron-optical objective in the vicinity of the sample, may damage the objective and/or its voltage supply.

The process gas or precursor gas may contain harmful gases. From a safety point of view, the frequent exchange of the gas containers of an SEM or FIB system caused by a high gas flow is undesirable.

Various solutions have been developed to satisfy these conflicting demands. For example, US 2005/0199806 A1 describes a specially shaped gas line system which allows a process gas to be directed symmetrically around a charged particle beam at a sample to be processed. U.S. Pat. No. 6,872,956 B2 describes a cascade-type pump arrangement with a forepump, two turbomolecular pumps and an ion getter pump. U.S. Pat. No. 9,070,533 B2 discusses the insertion of a process shroud, which is placed on the sample and has a gas feed, into the vacuum chamber of an SEM in order to minimize the amount of process gas needed to be supplied.

U.S. Pat. No. 8,921,811 B2 describes a process cell with a dedicated sample holder, a gas inlet and a gas outlet, and also an opening for a charged particle beam. The process cell reduces the amount of gas required for sample processing. Quite apart from the additional outlay connected with a process cell, the use thereof is restricted to small samples.

In a further embodiment for restricting the pressure increase caused by the process gas and/or its reaction products in the column, the column of the device has one or more openings to the HV environment of the microscope. The prior art uses a pressure stage tube which divides the column of the microscope into two parts in terms of pressure in order to additionally protect the sensitive parts, for instance optical or particle-optical components, stops, ion getter pumps, which are of essential importance to continuous maintenance of the high vacuum, and in particular protect the Schottky cathode used for the field emission. The pressure stage tube is a long (e.g., 15 mm), thin (diameter of 1 mm, for example) tube which enables the passage of the collimated particle beam. The pressure stage tube significantly reduces the conductance of the particles of the precursor gas and/or of its reaction products in the molecular flow pressure regime (for example to 0.01 l/s for nitrogen). The percentage of the process gas able to pass the pressure stage tube is of the order of 0.1%. This residual component is removed from the system using an ion getter pump connected upstream of the Schottky cathode.

However, this solution still has a few disadvantages. The pressure stage tube should be as long as possible and have a small diameter so that it provides good decoupling in terms of pressure of the lower part of the column from the above part of the apparatus. However, these demands lead to an impairment of the beam quality of the particle beam passing through the pressure stage tube on account of adsorption of particles of the process gas and/or its reaction products or on account of the deposition of other contaminants from the column. By way of example, these may cause a stigma and/or a drift of the particle beam. These effects may significantly reduce the process stability of the microscope.

On account of the small diameter of the pressure stage tube, the detector or detectors used to image the sample must be attached below the pressure stage tube. The particles emanating from the sample, which are used for detection purposes, have a significantly larger solid angle than the primary focused particle beam directed at the sample. Limiting the arrangement of the detector or detectors to within the microscope restricts the number of usable detector types since these must be able to withstand high concentrations of corrosive gases. Moreover, there is a problem relating to space below the objective of the microscope; its resolution can be maximized by virtue of minimizing the distance between the objective and the sample.

The incidence of low kinetic energy particles on the sample is preferred in order to minimize damage to the sample induced by the particle bombardment and in order to restrict the lateral extent of the local chemical reaction. However, especially in the case of low incidence energies of the particles of the particle beam on the sample, it is desirable to detect all particles emanating from the sample, especially the particles that emanate from the sample at a small polar angle in relation to the beam direction of the primary particle beam. However, it is necessary to this end to spatially separate the particles running substantially antiparallel to the particle beam from the latter. The long, tight above-described pressure stage tube prevents the passage of a significant portion of the particles emanating from the sample. However, shortening and/or widening the pressure stage tube leads to a pressure increase in the region above the modified pressure stage tube, to a level at which ion getter pumps, for example, are unable to operate any more.

Poor HV conditions are prevalent in the region of the column below the pressure stage tube. This means that the particle beam is exposed to the interaction with gas particles over a significant portion of its path to the sample. The scattering of the particles of the particle beam caused thereby results in a widening of its focal diameter.

### SUMMARY

In a general aspect, the present invention addresses the problem of specifying a device which allows the imaging and processing of a sample using a focused particle beam to be improved.

According to an exemplary embodiment of the present invention, this problem is at least partly solved by the subject matter of independent Claim 1 of the present application. Exemplary embodiments are described in the dependent claims.

In an embodiment, a device for imaging and processing a sample using a focused particle beam comprises: (a) at least one particle source which is configured to create a particle beam in an ultrahigh vacuum environment; (b) at least one sample chamber which serves to accommodate the sample and which is configured to image the sample in a high vacuum environment and process the sample in a medium vacuum environment; (c) at least one column which is arranged in a high vacuum environment and which has at least one particle-optical component configured to shape a focused particle beam from the particle beam and direct said focused particle beam at the sample; (d) at least one detection unit which is arranged within the at least one column and which is configured to detect particles emanating from the sample; (e) at least one gas line system which terminates at the outlet of the focused particle beam from the column and which is configured to locally provide at least one process gas at the sample with a pressure such that the focused particle beam is able to induce a particle beam-induced local chemical reaction for processing the sample; and (f) at least one pressure adjustment unit through which the particle beam and the particles emanating from the sample pass and which is configured to limit a pressure increase caused at the at least one detection unit as a result of processing the sample to a factor of 10 or less, preferably to a factor of 5 or less, more preferably to a factor of 3 or less, and most preferably to a factor of 2 or less, without impeding access of the particles emanating from the sample to the at least one detection unit.

As a result of the continuous use of the detection unit in an (at least) high vacuum (HV) environment, it is hardly still exposed to the action of corrosive gases that may arise when processing the sample. The range of detectors usable for imaging the sample is increased as a result of dropping this boundary condition. Further, a contamination of the detection unit, for instance by adsorption of gas particles on its detector surface, is effectively prevented. Moreover, the sensitive optical or particle-optical components of the column are protected from possible contamination or even damage as a result of unchanging HV conditions.

At the same time, a pressure adjustment unit according to the invention grants substantially all particles emanating from the sample unimpeded access to the detection unit. This enables realistic imaging of the sample. Moreover, the beam quality of a focused particle beam is not impaired during the passage through the pressure adjustment unit. This can avoid a reduction in the process stability. A device according to the invention thus allows a sample to be processed with a high local process gas concentration and at the same time prevents contamination of or even damage to the sensitive particle-optical components, and thus allows imaging of the sample with a high quality.

A medium vacuum (fine vacuum; FV) includes a pressure range from 1 mbar or 100 Pa to 10⁻³ mbar or 0.1 Pa. The HV regime adjoins the FV regime and includes the pressure range from 10⁻³ mbar to 10⁻⁸ mbar. Even lower pressures occur in the ultrahigh vacuum (UHV), specifically 10⁻⁸ mbar to 10⁻¹¹ mbar. Proceeding from atmospheric pressure or normal pressure and standard conditions (1013.25 mbar, 298 K), the mean free path lengths of the gas particles in the FV regime reach numerical values which exceed the dimensions of typical vacuum vessels, and an initially viscous gas flow transitions via a Knudsen flow into the regime of molecular gas flow. In the molecular flow regime, the gas particles no longer interact among themselves and only still interact with the walls of the vacuum vessel. In a device according to the invention, pressure conditions under which a molecular flow of gas particles is formed are prevalent everywhere—with the exception of the location at which the sample is processed.

The particles of a particle beam may be particles without a rest mass (m₀=0 kg), for instance photons, or comprise particles with a rest mass (m₀>0 kg), for instance electrons, ions, atoms or molecules. Electron beams are currently preferred. On the one hand, electrons have a short de Broglie wavelength on account of their low rest mass, allowing focusing onto a small spot diameter, and, on the other hand, the irradiation of a sample with electrons—unlike an ion bombardment, for example—causes no damage or only very small damage to the sample. The term particle-optical component comprises a component which can shape particles without a rest mass, for instance photons, and/or particles with a rest mass, for instance electrons, to form a focused particle beam.

Particles emanating from the sample can be photons, electrons and/or ions. The particles emanating from the sample preferably comprise secondary electrons (SE) and/or electrons scattered back from the sample (BE; backscattered electrons). Additionally, photons emitted by the sample can be used to analyze the sample if required.

The type of particle incident on the sample may be the same as is detected by the detection unit. However, it is also possible that a first particle type is incident on the sample and a second particle type is detected by the detection unit, with the first and the second particle type denoting different particle types. By way of example, the first particle type may comprise photons and/or ions, and the second particle type may comprise electrons.

In the region of the at least one detection unit and when no processing process is carried out, the at least one column may have a pressure of <10⁻⁵ mbar, preferably <3·10⁻⁶ mbar, more preferably <10⁻⁶ mbar, and most preferably <3·10⁻⁷ mbar.

A device according to the invention allows a detection unit to operate continuously in an HV environment. This broadens the spectrum of detectors which can be used in the detection unit.

In the region of the at least one particle source of the at least one column, a pressure increase as a result of processing the sample may remain <10⁻⁸ mbar, preferably <5·10⁻⁹ mbar, more preferably <10⁻⁹ mbar, and most preferably <10⁻¹⁰ mbar.

The at least one column may comprise a vacuum pump port and/or may comprise at least one pressure-type bypass port to the sample chamber.

A sample chamber comprises at least one port for a vacuum pump. Without a process gas being let in, the vacuum pump reduces the pressure in the sample chamber to a pressure in the HV regime, typically between approximately 10⁻⁵ mbar and 10⁻⁷ mbar. There is a local pressure increase in the sample chamber as a result of letting in the process gas and initiating a local chemical reaction which creates reaction products of the process gas and the sample. Some of the non-reacted process gas and the reaction products created are removed from the sample chamber via the latter's vacuum pump port.

The at least one vacuum pump port and/or the at least one pressure-type bypass port to the sample chamber can be arranged in the lower part of the at least one column.

Since the local chemical reaction occurs in the direct vicinity of the beam outlet of the focused particle beam from the column, some of the process gas and the reaction products generated may penetrate into the column of the device. The particles of the process gas, some of which are reactive or very reactive, and the reaction products, some of which have a corrosive effect, must be removed from the column as quickly as possible in order to avoid contamination of, or even damage to, the sensitive particle-optical components arranged in the column. The column comprises at least one port for a vacuum pump to this end. This vacuum pump port is positioned as close as possible to the outlet of the particle beam from the column in order to prevent an advance of the process gas and/or its reaction products into the upper parts of the column. Instead of a dedicated vacuum pump, the vacuum pump port of the column can be connected to a pressure-type bypass port (bypass) of the sample chamber and can be pumped by the vacuum pump of the sample chamber.

When reference is made hereinbelow to the lower part of the column, this means the part of the column where the focused particle beam leaves the column. The upper part of the column denotes the part where the particles of the particle beam source enter the column. Using this convention, the beam direction of the particle beam runs through the column of the device from top to bottom.

The device may also comprise at least one turbomolecular pump which pumps the at least one sample chamber. A turbomolecular pump may likewise be connected to the vacuum pump port of the sample chamber. In the inlet region, a turbomolecular pump requires pressures at which the gas particles already exhibit molecular flow. This vacuum pump type can generate pressures in the UHV regime.

The sample may comprise a photolithographic mask.

Current photolithographic masks typically have lateral dimensions of 152 mm×152 mm. To be able to process a photomask, the sample chamber of a device according to the invention needs to be large enough to be able to accommodate a mask. Moreover, the sample holder in the sample chamber comprises displacement elements which are able to displace a photomask over the active region thereof, typically 142 mm×142 mm.

The processing of photomasks or, more generally, samples may comprise a local removal of material. In this case, the process gas comprises at least one etching gas, for example xenon difluoride (XeF₂) or nitrosyl chloride (NOCl). The processing of a sample may also comprise the local deposition of material onto the sample. The process gas comprises at least one precursor gas to this end. The precursor gas may comprise a metal carbonyl, for instance dicobalt octacarbonyl (Co₂(CO)₈) or TEOS (tetraethyl orthosilicate, C₈H₂₀O₄Si). The process gas may also comprise an additive gas, which assists an etching of the sample and/or a deposition of material onto the sample. By way of example, an additive gas may comprise oxygen (O₂) or ammonia (NH₃).

The at least one gas line system may be configured to locally provide the at least one process gas at the sample, with a pressure ranging from 1 mbar to 0.001 mbar, preferably from 0.6 mbar to 0.003 mbar, more preferably from 0.3 mbar to 0.006 mbar, and most preferably from 0.1 mbar to 0.01 mbar.

The minimum local pressure of the process gas required so that the focused particle beam is able to trigger a local chemical reaction depends on the specific reaction. The local chemical reaction grinds to a halt below a reaction-specific minimal gas concentration. By contrast, a local pressure of the process gas which is as high as possible accelerates the chemical reaction and is therefore advantageous for reasons of process economics. A high local pressure of the process gas and, correlating therewith, of its reaction products however leads to a temporary breakdown in the HV conditions in the column, and the aforementioned accompanying disadvantageous effects of contamination or degradation of the sensitive optical or particle-optical components in the column.

The at least one particle source may be configured to create a particle beam with a current intensity of 0.1 pA to 10 nA, preferably 0.3 pA to 3 nA, more preferably 1 pA to 1 nA, and most preferably 3 pA to 0.3 nA.

The at least one particle-optical component may be configured to focus the particle beam onto a spot diameter of <5 nm, preferably <2 nm, more preferably <1 nm, and most preferably <0.8 nm.

The spot diameter is defined as R50, which is to say the radius within which 50% of the beam intensity is located. The radius of the minimum area in which a focused particle beam is able to process a sample as a result of triggering a particle beam-induced chemical reaction is larger by a factor of approximately 3 to 4.

The at least one detection unit may comprise a scintillation counter, in particular an Everhart-Thornley detector, and/or a semiconductor detector, in particular a direct electron detector.

A device according to the invention may further comprise at least one element from the following group: a magnetic prism, a magnetic chicane and a Wien filter, with the at least one element being arranged in the at least one column and being configured to steer the particles emanating from the sample to the at least one detection unit.

The use of a magnetic prism in order to steer the particles emanating from the sample onto the detection unit allows in particular the detection of particles whose trajectory runs substantially antiparallel to the direction of the particle beam. This portion of the particles emanating from the sample cannot be detected by an in-lens detector, for example, since the latter has an opening for the passage of the particle beam directed at the sample. To increase the lateral resolution of a particle beam, in particular an electron beam, the landing energy of the particles, which is to say the kinetic energy with which these strike the sample surface, is reduced as far as possible. This reduces the solid angle within which the particles emanate from the sample. However, this also means an increase in the portion of particles leaving the sample antiparallel to the focused particle beam. The imaging quality of the images recorded of the sample increases by virtue of the detection unit of a device according to the invention being able to detect these particles.

A device according to the invention may further comprise at least one electrode which is arranged at the outlet of the at least one column and which is configured to scan the focused particle beam over the sample. The at least one electrode may comprise an octupole electrode.

Moreover, a device according to the invention may comprise a charge compensating grid arranged below the gas line system at the output of the at least one column.

Moreover, the column of a device according to the invention may contain a liner tube (beam guiding tube), the lower part of which is inserted in the region of the particle beam outlet and which is configured to prevent or reduce contamination of the optical components by the process gas and its reaction products. The radiation tube is typically embodied in the form of a metal tube, for instance an aluminium tube, and may have a diameter of a few millimeters, for example 4 mm to 5 mm. An electrostatic potential may be applied to the metal tube, the said electrostatic potential, in combination with the charge compensating grid, creating an electric field which reduces the kinetic energy with which the particles of the focused particle beam are incident on the sample. By applying a voltage to the metal tube, the particles of the focused particle beam can be decelerated to a kinetic energy ranging from 100 eV to 1200 eV, preferably 130 eV to 1000 eV, more preferably 160 eV to 800 eV, and most preferably 200 eV to 600 eV.

On the one hand, reducing the landing energy of the particles of the focused particle beam reduces the area in which the particles cause a local chemical reaction. On the other hand, reducing the kinetic energy increases the probability of the particles of the focused particle beam scattering on the molecules of the process gas or its reaction products in the region in which a large pressure or a large particle density is created as a result of letting in process gas. This impairs the (lateral) control of the local chemical reaction.

On account of its large diameter, the liner tube only acts like a pressure stage to a small extent; typically, it can reduce the pressure by approximately a factor of 2.

The at least one pressure adjustment unit may comprise at least one element from the following group: a differentially pumped pressure stage, which is arranged in the at least one column, and at least one stop, which is arranged above the at least one gas line system at the outlet of the focused particle beam from the at least one column.

Both embodiments of the pressure adjustment unit render it possible for there to be no significant breakdown of the HV conditions at the position of the detection unit in the column, which is to say the detection unit and the further optical components in the part of the column thereabove are largely protected from corrosive gas particles. At the same time, substantially no particles emanating from the sample are impeded along their path to the detection unit, whereby the quality of imaging the sample by the focused particle beam is increased.

In this case, the expression “substantially” means that individual particles are scattered through a large angle away from the beam axis of the particle beam at a charge compensating grid, and so these cannot enter into the opening of the column. Further, applying a negative electrostatic potential (for example, 20 V to 200 V) to the charge compensating grid can prevent charged particles whose kinetic energy does not suffice to overcome this potential barrier from being able to leave the sample.

In the beam direction of the particle beam, the at least one differentially pumped pressure stage may be arranged in the region of a back-side focal plane of an objective lens in the at least one column.

Arranging the differentially pumped pressure stage at this beam position is advantageous since a beam waist of the beam envelope of the particles emanating from the sample is created at this location by the objective or the objective lens of the device. The differentially pumped pressure stage reduces by approximately two orders of magnitude the proportion of the process gas and its reaction products able to enter into the overlying part of the column. Without the differentially pumped pressure stage, one to two percent of the gas particles penetrating into the column from below might reach the upper part of the column. The differentially pumped pressure stage reduces this proportion to approximately 0.02%.

A device according to the invention may further comprise a turbomolecular pump for pumping a chamber of the at least one differentially pumped pressure stage.

Further, the column may have a vacuum pump port arranged in the upper part of the column.

A device according to the invention may comprise an ion getter pump for pumping the vacuum pump port in the upper part of the column.

Without the differentially pumped pressure stage, the pressure at this location of the column would be too high for an ion getter pump. The latter would run hot and fail. On account of the complex column structure and on account of problems with the vibration decoupling of the turbomolecular pump, it is not possible to ensure the required pressure level of <10⁻⁶ mbar in the upper part of the column if a turbomolecular pump, rather than an ion getter pump, is used to pump the upper part of the column.

The chamber of the at least one differentially pumped pressure stage may comprise a pressure-type bypass port to the sample chamber for pumping the inlet region of the chamber of the at least one differentially pumped pressure stage.

This configuration makes it possible to save one vacuum pump and as a result simplifies the design of a device according to the invention.

In the beam direction of the particle beam, the at least one differentially pumped pressure stage may be arranged upstream of the vacuum pump port of the column.

This arrangement ensures that the majority of the process gas penetrating into the column and its reaction products are already removed from the column by the latter's vacuum pump port.

The inlet region of the at least one differentially pumped pressure stage may comprise a pressure stage tube with a diameter of 1 mm to 3 mm, preferably 1.3 mm to 2.7 mm, more preferably 1.6 mm to 2.4 mm, and most preferably 1.9 mm to 2.1 mm, and with a length ranging from 5 mm to 25 mm, preferably from 7 mm to 18 mm, more preferably from 8 mm to 14 mm, and most preferably from 9 mm to 11 mm.

As a result of this dimensioning, the pressure stage tube has a molecular conductance of 0.10 l/s in the inlet region of the at least one differentially pumped pressure stage.

The outlet region of the at least one differentially pumped pressure stage may comprise a pressure stage tube with a diameter of 2 mm to 4 mm, preferably 2.3 mm to 3.7 mm, more preferably 2.6 mm to 3.4 mm, and most preferably 2.9 mm to 3.1 mm, and with a length ranging from 20 mm to 36 mm, preferably from 23 mm to 33 mm, more preferably from 26 mm to 30 mm, and most preferably from 27 mm to 29 mm.

As a consequence of this dimensioning, the pressure stage tube has a molecular conductance of 0.12 l/s in the outlet region of the at least one differentially pumped pressure stage. This numerical value and further conductance values specified in this application relate to nitrogen gas. If other gases are used to examine the pressure-related conditions in the device, then the molecular conductance values change proportionally to the mass number of the gas used in relation to the mass number of nitrogen.

A chamber of the at least one differentially pumped pressure stage may have a height ranging from 5 mm to 30 mm, preferably 6 mm to 20 mm, more preferably 7 mm to 15 mm, and most preferably 8 mm to 12 mm. Further, the chamber of the at least one differentially pumped pressure stage may have a width from 10 mm to 30 mm, preferably 13 mm to 27 mm, more preferably 16 mm to 24 mm, and most preferably 19 mm to 21 mm. Moreover, the chamber may have a length of 50 mm to 200 mm, preferably 70 mm to 150 mm, more preferably 90 mm to 120 mm, and most preferably 95 mm to 110 mm.

A great height of the chamber of the differentially pumped pressure stage increases the molecular conductance thereof in the direction of the pump and consequently leads directly to a larger pump cross section. As a result, the upper part of the column is decoupled well in terms of pressure from its lower part. On the other hand, a large chamber height increases the path to the detection unit of the particles emanating from the sample, and the beam expansion accompanying this.

The chamber of the differentially pumped pressure stage may have a molecular conductance which is greater than the molecular conductance of the outlet part of the differentially pumped pressure stage by a factor of 10, preferably a factor of 15, more preferably a factor of 18, and most preferably a factor of 20.

Moreover, the chamber of the at least one differentially pumped pressure stage may be at the potential of the metal tube which is inserted into the column at the beam outlet.

The at least one stop may have an adjustable aperture.

By attaching a stop directly above the region of the gas inlet, it is possible to significantly reduce the volume which needs to be filled with process gas for the purpose of carrying out the local chemical reaction. This minimizes the amount of process gas required. This is advantageous in that the gas container or containers of a device according to the invention only require infrequent replacement. Moreover, the reduced volume to be filled with process gas reduces the time interval required to build up and reduce the necessary pressure at the reaction location. Moreover, a stop attached directly above the gas line system reduces the portion of the process gas and its reaction products which can penetrate into the column of the device and need to be pumped out of the latter.

Moreover, adjusting the aperture can ensure that, firstly, substantially all particles emanating from the sample are able to pass through the stop and, at the same time, it is possible to minimize the proportion of the process gas and its reaction products which are able to enter the column. Moreover, adjusting the opening of the stop makes it possible to adapt the aperture width thereof to the distance between the stop and a sample surface. Finally, a stop at the outlet of the column reduces the length of the path with a high gas concentration which the focused particle beam must pass along. Consequently, the probability of its particles being scattered at the gas particles is low, and there is no enlargement of the focal spot on the sample surface.

The at least one stop may comprise at least one piezo actuator which is configured to adjust the aperture.

The stop opening may have any shape. Simple geometric shapes, for example rectangles or squares, the openings of which can be modified by simple piezo actuator arrangements, are preferred.

The at least one piezo actuator may change the area of the aperture by a factor of 1.1, preferably by a factor of 1.2, more preferably by a factor of 1.5, and most preferably by a factor of 2.0.

A device according to the invention may further comprise a voltage supply configured to apply an electrostatic potential to the at least one stop.

By applying an electrostatic potential to the stop, it is possible to remove or at least reduce a distortion of the electric field between the liner tube and a charge compensating grid. The voltage supply may apply an electrostatic potential ranging from 20 V to 1000 V, preferably from 50 V to 600 V, more preferably from 100 V to 400 V, and most preferably from 150 V to 300 V, to the at least one stop.

The aperture of the stop can be bigger than a distance of the aperture from a sample surface, preferably bigger by a factor of 1.5, more preferably bigger by a factor of 1.8, and most preferably bigger by a factor of 2.0.

The aperture may range from 100 μm to 3000 μm, preferably 130 μm to 2000 μm, more preferably 160 μm to 1000 μm and most preferably 200 μm to 600 μm.

In the case of a factor of 2 of the quotient of stop diameter and distance from the sample surface, the component of the process gas entering the column can be reduced by a factor of 10 for small distances between stop and sample surface. This can reliably prevent an ion getter pump, which pumps the upper part of the column, from becoming overloaded.

A distance between the aperture and the sample surface may range from 80 μm to 1000 μm, preferably 100 μm to 800 μm, more preferably 150 μm to 700 μm and most preferably 200 μm to 600 μm.

A charge compensating grid may have a grid opening from 10 μm to 50 μm, preferably 15 μm to 45 μm, more preferably 20 μm to 40 μm and most preferably from 25 μm to 35 μm.

The distance between the charge compensating grid and the sample surface may be half the size of a grid opening in the charge compensating grid.

The device may further comprise a computer system having at least one non-volatile storage medium. The computer system may be configured to control the device during the imaging of the sample and/or the processing of the sample.

A computer program may comprise instructions which prompt a computer system to image a sample and/or process a sample. In particular, the computer system may comprise instructions which adjust a working distance of the column from a sample and/or which control an adjustment of the opening in the stop.

### BRIEF DESCRIPTION OF DRAWINGS

The detailed description that follows describes currently preferred exemplary embodiments of the invention with reference to the drawings, wherein:

FIG. 1 presents a schematic section through a device according to the prior art for imaging using an electron beam and for processing a sample using the electron beam and at least one process gas;

FIG. 2 reproduces an enlarged section of a part of the column of the device from FIG. 1;

FIG. 3 presents a schematic section through a device in which a detector or detection unit is arranged behind a pressure stage, which is to say upstream, in the upper part of the column;

FIG. 4 illustrates the device from FIG. 3 following the installation of a differentially pumped pressure stage;

FIG. 5 presents a simulation, along the column of the device from FIG. 4, of a beam envelope of the electrons emanating from a sample as generated by an electron beam incident on the sample surface with little kinetic energy;

FIG. 6 schematically illustrates the molecular gas flow over the pressure stage of the device from FIG. 3 in the upper partial image and, in the lower partial image, schematically illustrates the molecular gas flows into the differentially pumped pressure stage, and out of the latter, in the device from FIG. 4;

FIG. 7 reproduces the lower part of the column from FIG. 3 in the upper partial image and, in the lower partial image, reproduces the beam fanning of the electrons of a focused particle beam as a consequence of scattering at the particles of a process gas let into the sample chamber; and

FIG. 8 shows the installation of a stop into the outlet of the column of the device from FIG. 2 in the upper portion and, in the lower partial image, illustrates the reduction in the beam fanning of the primary focused particle beam caused as a result.

### DETAILED DESCRIPTION

Currently preferred embodiments of devices according to the invention are explained hereinbelow. Two embodiments of a device according to the invention are explained in detail using the example of a scanning electron microscope (SEM). However, devices according to the invention are not restricted to the use of a beam of particles with mass, in the form of an electron beam. Instead, any particle beam using particles in the form of bosons or fermions can be used in these devices. Further, the use of devices according to the invention is explained using the example of imaging and processing a photolithographic mask. However, this does not represent any restriction. Rather, devices according to the invention can be used for imaging and processing any desired sample. By way of example, the devices described in this application can be used to image and modify chip structures or semiconductor structures on wafers, MEMS (micro-electromechanical systems) and/or PICs (photonic integrated circuits) by use of a particle beam or by use of a particle beam-induced processing process.

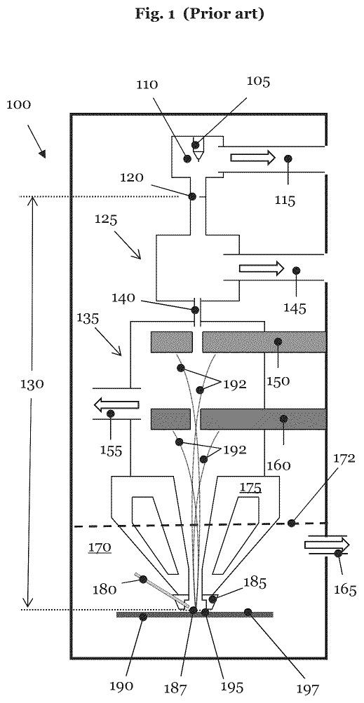

FIG. 1 represents a schematic section through a device 100 for imaging and processing a sample 190 using a focused electron beam as an example of a focused particle beam. The particle source 110 or electron source 110 comprises a Schottky field emitter 105, from which electrons are released in a strong electric field in an ultrahigh vacuum (UHV) environment (1·10⁻¹⁰ mbar≤p≤·3·10⁻⁹ mbar). The electron source 110 comprises a vacuum port 115, to which an ion getter pump (not depicted in FIG. 1) can typically be connected. The electron beam passes through the stop 120 and enters the upper part 125 of the column 130 of the device 100.

In FIG. 1, and all subsequent figures, the particle source 110 is flange-mounted to the column 130 at the top of the upper end of the upper part 125. The particle beam enters the column 130 at the upper end and leaves said column at its lower outlet 187. Using this convention, the beam direction of the particle beam runs from top to bottom. Upstream means a direction counter to the beam direction, which is to say upward, and downstream denotes the beam direction of the particle beam, which is to say downward.

In the example of FIG. 1, the upper part 125 and the lower part 135 of the column 130 contain the electron-optical components for focusing and directing the electron beam at the sample 190. The upper 125 and the lower part 135 of the column 130 are separated from one another by a pressure stage tube 140. The pressure stage tube 140 is designed so that the electron beam can pass through the latter but the upper part 125 of the column 130 is largely shielded from a pressure variation in the lower part 135 of the column 130. A long thin pressure stage tube 140 is advantageous to this end. Gas particles can be adsorbed at the inner wall of a long thin pressure stage tube 140. This may result in a degradation of the beam quality of the electron beam passing through the pressure stage tube 140. This may adversely affect the imaging behavior of the electron beam of the device 100. Moreover, the disturbed beam profile of the focused electron beam may negatively affect the quality of a processing process.

The pressure is reduced to a value of approximately 1·10⁻⁷ mbar (typically 5·10⁻⁸ mbar to 5·10⁻⁷ mbar) in the upper part 125 of the column 130, typically with the aid of an ion getter pump which is connected to the vacuum port 145 and which is not depicted in FIG. 1.

However, the opening of the pressure stage tube 140 is not large enough to allow the majority of the electrons 192 emerging from the sample 190 to pass. The device 100 of FIG. 1 therefore has two so-called in-lens detectors 150, 160, which are arranged in the lower part 135 of the column 130. However, varying pressure conditions prevail in the column 130 below the pressure stage tube 140. These are caused by letting a process gas into the process chamber 170 by way of the gas line system 180. Without letting in a process gas by way of the gas line system 180, the pressure level in the lower part 135 of the column 130 ranges from 10⁻⁵ mbar to 10⁻⁶ mbar, which is to say stable HV conditions are prevalent.

When a processing process in which the focused electron beam initiates a local chemical reaction on the surface 197 of a sample 190 is carried out, there is an increase in the pressure level to between 10⁻² mbar and 10⁻⁴ mbar in the lower part 135 of the column 130. The detectors 150 and 160 are therefore exposed to a considerable gas concentration. The gases in the lower part 135 of the column 130 comprise a significant amount of non-reacted process gas and reaction products of the process gas. These typically reactive gases have a significant corrosive potential which may contaminate or damage the detectors 150, 160 and the further electron-optical components housed in the lower part 135 of the column 130, for instance the objective 175.

The lower part 135 of the column 130 comprises a vacuum pump port 155. By way of the latter, the lower part 135 of the column 130 can be evacuated, for example with the aid of a turbomolecular pump (not shown in FIG. 1). Alternatively, as depicted schematically in FIG. 1, the vacuum pump port 155 may form a pressure-type bypass port to the sample chamber 170. The dashed horizontal line 172 illustrates the upper end of the sample chamber 170. The sample chamber 170 in turn comprises a vacuum pump port 165, by way of which said chamber can be pumped. For example, a turbomolecular pump (not reproduced in FIG. 1) may likewise be used to this end.

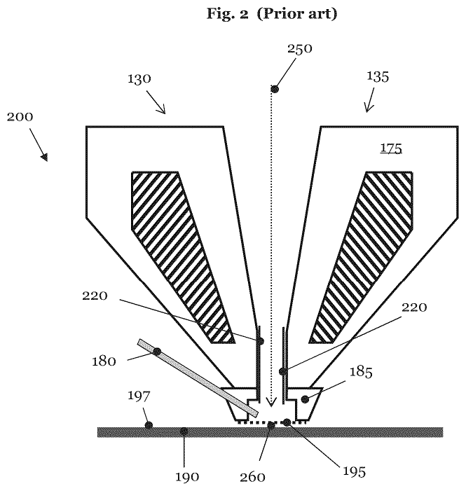

In addition to the detectors 150 and 160, the lower part 135 of the column 130 of the device 100 comprises at least one electron-optical objective 175 or one objective lens 175, which focuses the electron beam onto the sample 190. The part of the column 130 in which the objective lens 175 is arranged is reproduced again in enlarged fashion in the diagram 200 in FIG. 2. At the outlet of the focused electron beam 250—as an example of a focused particle beam 250—from the column 130, the latter comprises an octupole electrode 185, with the aid of which the focused electron beam 250 can be scanned over the sample 190. Additionally, the gas line system 180 terminates in the octupole electrode 185. The gas line system 185 provides the process gas in the region of the point of incidence 260 of the focused electron beam 250 on the sample 190.

Opening the gas line system 180 may result in the pressure in the region where a local chemical reaction is carried out increasing to between 10⁻¹ mbar and 10⁻³ mbar, which is to say into the FV regime. The schematic representation in FIG. 2 illustrates that the majority of the non-reacted particles of the process gas and the locally generated reaction products are able to penetrate into the column 130 of the device 100.

To ensure the imaging quality of the electron beam, especially in the case of low landing energies of the electrons, the components along the beam path of the electron beam in the column 130 are at an electric potential which corresponds to that of the electrons in the column 130, up to the outlet 187 thereof. To ensure this requirement even in the tight outlet 187 of the electron beam from the column 130, an interchangeable metal tube 220 is typically inserted into the outlet 187 of the column 130. This metal tube is referred to as a liner tube 220. As a rule, the liner tube 220 is manufactured from a non-magnetic and corrosion-resistant material and has a diameter of 4 mm to 5 mm. The liner tube 220 limits the diameter of the column outlet 187 in defined manner and thus has the positive side-effect of counteracting the contamination of the electron-optical, or generally particle-optical, components which are housed in the lower part 135 of the column 130.

The column 130 of the exemplary device 100 of FIGS. 1 and 2 comprises a charge compensating grid 195, which is tasked with minimizing the effects of electrostatic charging of the sample 190. To meet this requirement, the distance between the charge compensating grid 195 and the sample surface 197 is chosen to be very small. Typical numerical values of this distance are <70 μm. A sample 190 in the form of an electrical insulator, for instance a photolithographic mask 190, may charge as a consequence of being irradiated by a focused electron beam 250. A photolithographic mask frequently comprises an electrically insulating quartz substrate.

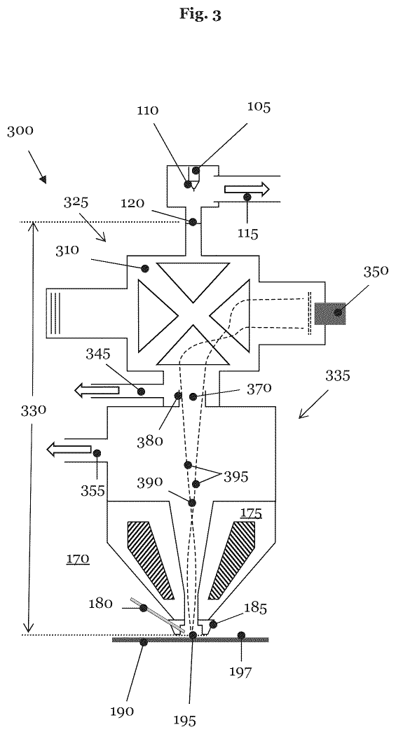

The device 300 from FIG. 3 schematically shows a column 330 in which a detection unit 350 or detector 350 can operate at a lower pressure level in comparison with the detectors 150, 160 from FIG. 1. The detector 350 may be a scintillation detector 350, for example an Everhart-Thornley detector 350, and/or comprise a semiconductor detector, in particular a direct electron detector. The sample chamber 170 from FIG. 1 has not been depicted in FIG. 3, or the subsequent figures, for reasons of simplicity.

At the transition from its lower part 335 to its upper part 325, the column 330 has a pressure stage 370 with a pressure stage tube 380. To protect the detection unit 350 from an exposure to reactive gases, the latter—unlike the detectors 150 and 160 in the device 100 from FIG. 1—is installed upstream, into the upper part 325 of the column 330. The opening of the pressure stage tube 380 of the pressure stage 370 is dimensioned so that substantially all electrons 390 emanating from the sample 190 can reach the detector 350. The molecular conductance of the pressure stage 370 is of the order of 0.12 l/s (l/s represents liters per second) and hence approximately 13 times greater than the molecular conductance of the pressure stage tube 140 of the column 130 in the device 100.

In FIG. 3, the dashed line illustrates the beam envelope 395 of the electron beam 390 emanating from the sample 190 or of the electron distribution 395 generated by the sample. In the device 300 depicted in FIG. 3 in exemplary fashion, the pressure stage tube 380 has a diameter of 3 mm and a length of 28 mm. The pressure stage tube 380 impedes neither the primary electron beam 250, which emanates from the electron source 110 and is focused on the sample 190, nor the electron distribution 395, which is generated by said sample, on its path to the detection unit 350.

However, during a processing process of the sample 190, the pressure stage 370 allows breakdowns in the HV environment in the part 325 of the column 330 located thereabove, to a pressure level >10⁻⁵ mbar, which an ion getter pump (not shown in FIG. 3) connected to the vacuum pump port 345 is unable to process. The vacuum pump port 345 serves to evacuate the upper part 325 of the column 330 and corresponds to the vacuum pump port 145 of the device 100 from FIG. 1.

If a vacuum pump that can handle these pressure levels, for instance a turbomolecular pump, is connected to the vacuum port 345 rather than an ion getter pump, then the required residual gas pressure level of <10⁻⁷ mbar is not achieved in the upper part 325 of the column 330. However, this is required, firstly, to reliably protect the electron-optical or particle-optical components in the upper part 325 of the column 330 and, secondly, to adapt the pressure level in the upper part 325 of the column 330 to the UHV level of the electron source 110. While the sample 190 is imaged, the detector 350 “sees” a significantly lower pressure level than the detectors 150 and 160; however, said pressure level breaks down to an unacceptable level during a processing process. More than 2% of the reactive process gas or its reaction products are able to overcome the pressure stage 370 and advance into the upper part 325 of the column 330.

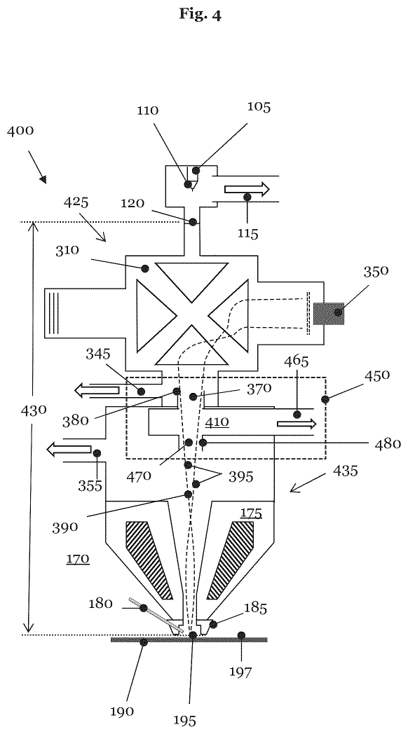

The device 400 from FIG. 4 corresponds to the device 300 from FIG. 3, albeit with the difference that a differentially pumped pressure stage 450 has additionally been installed. The latter is installed into the column 330 downstream, below the pressure stage 370 of the device 300. This means that the outlet region 370 of the differentially pumped pressure stage 450 corresponds to the pressure stage 370 in the device 300 from FIG. 3. The pressure stage tube 380 of the differentially pumped pressure stage 450 is the pressure stage tube 380 of the pressure stage 370 from FIG. 3.

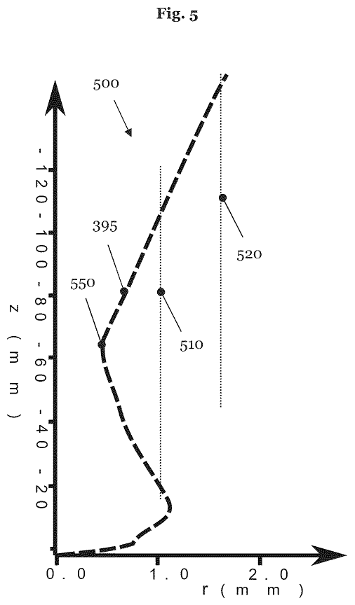

The differentially pumped pressure stage 450 has an inlet region 470, which is formed by a pressure stage tube 480. The opening of the pressure stage tube 480 can be dimensioned to be slightly smaller than that of the pressure stage tube 380 since the beam envelope 395 of the electrons 390 emanating from the sample expands counter to the beam direction of the primary focused particle beam 250. This is explained in detail hereinbelow on the basis of FIG. 5. The differential pressure stage 450 depicted in FIG. 4 in exemplary fashion comprises a pressure stage tube 480 with an opening diameter of 2 mm and a length of 10 mm. Hence, the pressure stage tube 480 has a molecular conductance of approximately 0.1 l/s.

Two contradictory demands are placed on the chamber 410 of the differentially pumped pressure stage 450. Firstly, the latter should have a molecular conductance that is as large as possible in order to decouple the inlet part 470 to the best possible extent in terms of pressure from the outlet part 370 of the differentially pumped pressure stage 450, so that the greatest possible proportion of the gas particles flowing into the chamber 410 via the inlet part 470 leave the chamber 410 via the latter's vacuum pump port 465. To this end, the chamber 410 should be as high as possible. However, this demand lengthens the path to the detector 350 for the electrons 390 emanating from the sample 190 and therefore broadens their beam envelope 395. Simulations have yielded a chamber height of the order of 10 mm as a good compromise. Moreover, the chamber 410 has a width of 20 mm and a length of 100 mm.

The vacuum pump port 465 of the differentially pumped pressure stage 450 may for example be pumped using a turbomolecular pump. For example, if a turbomolecular pump with a pumping capacity of 10 l/s is connected to the vacuum port 465, then the proportion of the process gas and its reaction products which can advance beyond the differentially pumped pressure stage 450 into the upper part 425 of the column 430 is of the order of 0.02%. This remaining proportion can be removed without problems via the vacuum pump port 345 of the upper part 425 of the column. This means that the pressure level in the upper part 425 of the column 430 is so low that the vacuum pump port 345 can be safely pumped by an ion getter pump, for example.

Following the installation of the differentially pumped pressure stage 450, the column 430 of the device 400 meets the two contradictory demands. The sensitive electron-optical components of the column 430 and, in particular, the detection unit 350 are reliably protected against vacuum breakdowns and hence from contamination. The electrons 390 leaving the sample 190 are not impeded along their path to the detection unit 350.

Diagram 500 in FIG. 5 presents a simulation of the variation of the diameter of the beam envelope 395 of the electrons 390 emanating from the sample 190 (x-axis) against the distance from the sample surface (y-axis). The electrons 390 emanating from the sample 190 are generated by a primary focused electron beam 250, the electrons of which have a low kinetic energy of approximately 200 eV at the sample surface 197. The beam envelope 395 has a beam waist 550 with a diameter of approximately 1 mm approximately 65 mm above the sample surface 197. This is caused by the imaging effect of the electron-optical objective 175. The waist 550 of the beam envelope 395 marks the back-side focal plane of the objective 175.

The diameter of the beam envelope 395 is less than 2 mm at a distance from approximately 25 mm to 105 mm, as illustrated by the dashed straight line 510. Within this distance from the sample surface 197, the pressure stage tube 480 of the differentially pumped pressure stage 450 grants the electrons 390 emanating from the sample 190 unimpeded access to the differentially pumped pressure stage 450. The diameter of the beam envelope 395 is less than 3 mm up to a distance of approximately 140 mm from the sample surface 197. This is symbolized in FIG. 5 by the dashed straight line 520. This means that the electrons 390 emanating from the sample 190 can pass the pressure stage tube 380 of the differentially pumped pressure stage 450 unimpeded provided the distance of the latter from the sample surface 197 is less than 140 mm. The design of the differentially pumped pressure stage 450 can be optimized and the best possible placement thereof in the column 430 of the device 400 can be determined on the basis of simulations of the trajectories of the electrons 390 emanating from the sample 190.

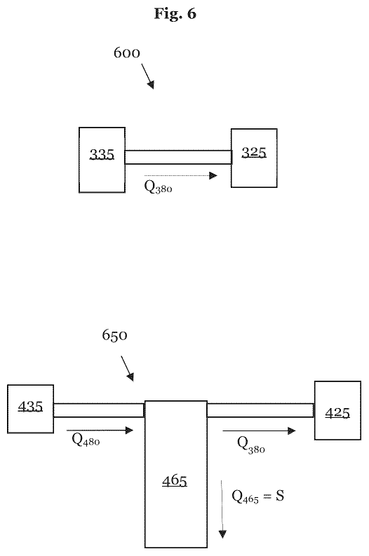

The upper partial image 600 in FIG. 6 illustrates the molecular flow of the gas particles within the column 330 from FIG. 3, from the latter's lower part 335 to the latter's upper part 325 via the pressure stage 370. A few fundamental equations for estimating molecular streams or molecular flows through the pressure stage 370 and into the differentially pumped pressure stage 450 or out of the latter are specified below. Under molecular flow conditions, the molecular conductance for nitrogen, specified in l/s (liters per second), in a tube of length L [cm] and diameter d [cm] is given by the following equation: C=12.1·d³/L (cf for example: “Handbuch Vakuumtechnik”, ISBN 978-3-658-13386-5).

The molecular flow Q (in units of mbar·l/s) is driven by a pressure difference or pressure gradient Δp. The constant of proportionality is the molecular conductance C introduced above: Q=C·Δp. This equation is equivalent to the fundamental electrical equation: I=(1/R)·U.

The molecular conductance for the pressure stage tube 380 of the pressure stage 370 was specified above as C₃₈₀=0.12 l/s. A pressure difference of 10⁻³ mbar between the lower part 335 and the upper part 325 of the column 330 results in a molecular stream or molecular flow of Q₃₈₀=0.12 l/s·10⁻³ mbar=1.2·10⁻⁴ mbar·l/s.

The lower partial image 650 in FIG. 6 illustrates the molecular streams or molecular flows in the differentially pumped pressure stage 450. A molecular gas flow Q₄₈₀ streams into the chamber 410 of the differentially pumped pressure stage 450 via the pressure stage tube 480 of the differentially pumped pressure stage 450. There, it branches into the molecular streams or molecular flows Q₄₆₅ and Q₃₈₀, which leave the chamber 410 via the vacuum port 465 and the pressure stage tube 380. The molecular stream 465 or the molecular flow 465 is proportional to the suction capacity S (in l/s) of a vacuum pump at a pressure p in the chamber 410 of the differentially pumped pressure stage 450: Q₄₆₅=S·p₄₁₀.

The molecular conductance of the pressure stage tube 480 of the differentially pumped pressure stage 450 was specified above as C₄₈₀=0.1 l/s. In the case of a pressure difference of 10⁻³ mbar between the lower part 435 of the column 430 and the chamber 410, there is a molecular flow Q₄₈₀ from the lower part 435 of the column 430 into the chamber 410 of the differentially pumped pressure stage 450: Q₄₈₀=0.1 l/s·10⁻³ mbar=10⁻⁴ mbar·l/s. To a first approximation, in the case of a suction capacity of S=10 l/s of the vacuum pump connected to the vacuum port 465 of the differentially pumped pressure stage 450, a pressure sets in in the chamber 410 of said pressure stage: p₄₁₀=Q₄₈₀/S=10⁻⁴ mbar·l/s/(10 l/s)=10⁻⁵ mbar.

As specified above, the pressure stage tube 380 has a molecular conductance of C₃₈₀=0.12 l/s at the outlet of the differentially pumped pressure stage 450. A pressure difference of 10⁻⁵ mbar drives a molecular flow Q₄₈₀=0.12l/s·10⁻⁵ mbar=1.2·10⁻⁶ mbar·l/s. This means that the differentially pumped pressure stage 450 reduces the molecular flow in the upper part 425 of the column 430 by two orders of magnitude: Q₃₈₀/Q₄₈₀=1.2·10⁻⁴ mbar·l/s/(1.2·10⁻⁶ mbar·l/s)=100. Only approximately 1% of the gas particles flowing into the chamber 410 of the differentially pumped pressure stage 450 leave the latter via the outlet region 370.

The electrical analogue to the differentially pumped pressure stage 450 is a voltage divider. By virtue of the load resistance R_{L} (corresponding to 1/C₄₆₅) being made to be small in relation to the resistance R₂ (corresponding to 1/C₄₈₀), the current (the molecular gas flow) flows largely via the load resistor R_{L} and no longer via the resistor R₂.

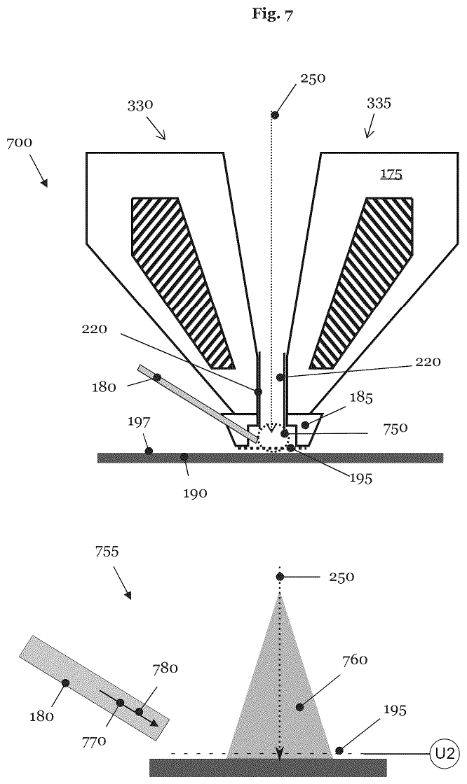

The upper partial image 700 in FIG. 7 reproduces once again the lower part 335 of the column 330 of the device 300 from FIG. 3. The detail of the dotted circle 750 is reproduced again in enlarged fashion in the lower partial image 755 in FIG. 7. As already explained in the context of FIG. 3, the provision of a process gas 770 at the sample surface 197 via the gas line system 180 leads to a significant pressure increase in the outlet region of the focused particle beam 250 or electron beam 250 from the column 330. The locally significantly increased concentration of gas particles results in the electrons of the focused electron beam 250 being scattered at the gas particles of the process gas 770 and thus brings about unwanted beam fanning, which is illustrated by the cone 760 in the partial image 755. Depending on the set gas pressure and the kinetic energy of the focused particle beam 250, up to 50% of the electrons may be scattered once or multiple times in the outlet region 750. As a result of the scattering, the lateral dimensions of a local chemical reaction initiated in the process gas 770 by the focused electron beam 250 are increased in a manner that is difficult to predict. The limit at which the concentration of the process gas and the concentration of the electrons are no longer sufficient to maintain a local chemical reaction depends on a number of parameters. The local processing process performed on the sample 190 can only be controlled with difficulties under these conditions.

The molecular gas flow penetrating into the column 335 is proportional to the process gas flow 780 of the gas line system 180. For the column 330 of the device 300 depicted in FIG. 3, approximately 1.5% of the particles of the process gas 770 or of the reaction products of the process gas 770 are able to penetrate into the lower part 335 of the column 330.

The partial image 755 further shows the charge compensating grid 195 from FIG. 1. The latter is typically a few ten micrometers above the sample surface 197 during the operation of the device 300. The charge compensating grid 195 may be grounded in order to minimize the effects of the charging of the sample surface 197 due to the focused electron beam 250. Further, the potential of the charge compensating grid 195, in combination with the potential of the liner tube 220 which is at the potential of the electron-optical objective 175, serves to generate an electric field (not depicted in FIG. 7), in which the focused electron beam 250 is decelerated to a specified landing energy.

Further, a voltage U2 ranging from −20 V to −200 V may be applied to the charge compensating grid 195. The electric field, generated as a result, between the charge compensating grid 195 and the sample surface represents an energy barrier or energy filter for the electrons emanating from the sample 190. Only electrons with a kinetic energy greater than the energy barrier are able to leave the sample 190 and enter the column 330.

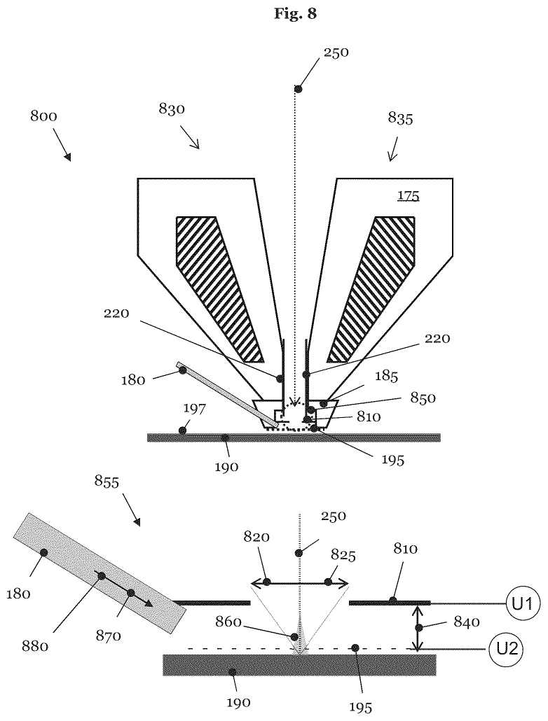

The upper partial image 805 in FIG. 8 presents the lower part 335 of the column 330 from FIG. 3. A stop 810 has additionally been inserted into the outlet of the column 330, in the region of the octupole electrode 185. The region 850 at the outlet of the column 830 is presented again in enlarged fashion in the lower partial image 855.

The stop 810 has been inserted into the electrode 185 above the end of the gas line system 180. The stop 810 and the sample 190 form a type of pressure chamber without lateral walls. The two-sided delimitation of the volume of the process gas 870 optimizes the amount of process gas 870 required. To allow the focused electron beam 250 to strike the sample surface 197 and to grant the electrons 390 emanating from the sample 190 access to the lower part 835 of the column 830, the stop 810 has an opening 820 with a diameter 825. The opening 820 of the stop 810 determines the largest angle at which the electrons 390 emanating from the sample 190 can leave the sample 190. The opening diameter 825 of the stop 810 may for example range from 200 μm to 2000 μm.

The stop diameter 825 or the opening diameter 825 can be varied with the aid of one or more piezo actuators, which are not shown in FIG. 8. Depending on the distance 840 between the sample surface 197 and the stop 810, the diameter 825 of the stop 810 can be chosen to be just so large that the entrance into the column 830 of the electrons 390 emanating from the sample 190 is not impeded. At the same time, this ensures that the proportion of the process gas flow and molecular flow of the reaction products which undesirably likewise penetrate into the column 830 is minimized. If the distance 840 is chosen to be half as large as the opening diameter 825, then the stop 810 has an aperture angle of 90° for the electrons 390.

The distance 830 of the stop 810 from the sample surface 197 is typically less than or equal to approximately one millimeter. Currently preferred distances 840 range between 100 μm and 300 μm. The distance 840 between the stop 810 and the sample surface 197 can be adjusted by raising or lowering the sample 190 with the aid of a sample holder (not shown in FIG. 8) to a numerical value within a working distance of the device 800.

Approximately 1.5% of the process gas 870 or its reaction products penetrate into the lower part 835 of the column 830 in the case of an opening diameter 825 of 2 mm and a distance 840 of 1 mm. This proportion reduces by one order of magnitude to 0.15% in the case of an aperture 825 of 400 μm and a distance of 200 μm. If the two sizes are halved again, the gas proportion penetrating into the column 830 reduces to approximately 0.05%.

Moreover, the stop 810 effectively shortens the length of the path under high gas pressure along which the electrons of the focused electron beam 250 travel to the sample surface 197, to distances <1 mm. The focused electron beam 250 experiences only very little beam fanning 860 under these conditions.

Further, an electrostatic potential can be applied to the stop 810; this is illustrated in FIG. 8 by U1. As a result, a distortion of the electric field between the liner tube 220 and the charge compensating grid 195 as a result of the stop 810 can be largely avoided.

The stop 810 effectively prevents a variation in the pressure level due to a processing process on the sample 190 in the upper part 825 of the column 830 in the case of appropriate dimensioning of the said stop's distance 840 from the sample surface 197 and the said stop's aperture width 825. Hence, in combination with the pressure stage 370 of the column 830, the stop 810 effectively protects the sensitive electron-optical components in the upper part 825 of the column 830, for example the detector 350, from the influence of reactive particles of the process gas 870 and its reaction products. By virtue of the stop 810 minimizing the proportion of the process gas 870 and its reaction products, the said stop likewise prevents contamination of and/or damage to the components arranged in the lower part 835 of the column 830, for instance the objective 175.

Naturally, it is also possible to combine the stop 810 of the device 800 with the differentially pumped pressure stage 450 of the device 400.

In some implementations, the computer system configured to control the device during the adjustment of various components of the device and/or the imaging of the sample and/or the processing of the sample can be implemented using one or more computers that include one or more one or more data processors configured to execute one or more programs that include a plurality of instructions according to the principles described above. In some implementations, the processing of data described above, such as processing the data generated from the detectors in the device, can be performed by the computer system.

The one or more computers can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker. In some implementations, the one or more computers can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives, magnetic disks, e.g., internal hard disks or removable disks; magneto-optical disks, and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention has been described with reference to exemplary embodiments, it is modifiable in various ways.

What is claimed is:

1. A device for imaging and processing a sample using a focused particle beam, comprising:
a. at least one particle source which is configured to create a particle beam in an ultrahigh vacuum environment;
b. at least one sample chamber which serves to accommodate the sample and which is configured to image the sample in a high vacuum environment and process the sample in a medium vacuum environment;
c. at least one column which is arranged in a high vacuum environment and which has at least one particle-optical component configured to shape a focused particle beam from the particle beam and direct said focused particle beam at the sample;
d. at least one detection unit which is arranged within the at least one column and which is configured to detect particles emanating from the sample;
e. at least one gas line system which terminates at the outlet of the focused particle beam from the column and which is configured to locally provide at least one process gas at the sample with a pressure such that the focused particle beam is able to induce a particle beam-induced local chemical reaction for processing the sample; and
f. at least one pressure adjustment unit through which the particle beam and the particles emanating from the sample pass and which is configured to limit a pressure increase caused at the at least one detection unit as a result of processing the sample to a factor of 10 or less, preferably to a factor of 5 or less, more preferably to a factor of 3 or less, and most preferably to a factor of 2 or less, without impeding access of the particles emanating from the sample to the at least one detection unit.

2. The device of claim 1, wherein the at least one column, in the region of the at least one detection unit, has a pressure of <10⁻⁵ mbar, preferably <3·10⁻⁶ mbar, more preferably <10⁻⁶ mbar, and most preferably <3·10⁻⁷ mbar.

3. The device of claim 1, wherein the at least one column comprises a vacuum pump port and/or at least one pressure-type bypass port to the sample chamber.

4. The device of claim 1, wherein the sample comprises a photolithographic mask.

5. The device of claim 1, wherein the at least one gas line system is configured to locally provide the at least one process gas at the sample, with a pressure ranging from 1 mbar to 0.001 mbar, preferably from 0.6 mbar to 0.003 mbar, more preferably from 0.3 mbar to 0.006 mbar, and most preferably from 0.1 mbar to 0.01 mbar.

6. The device of claim 1, wherein the at least one detection unit comprises a scintillation counter, in particular an Everhart-Thornley detector, and/or a semiconductor detector, in particular a direct electron detector.

7. The device of claim 1, further comprising at least one element from the following group: a magnetic prism, a magnetic chicane and a Wien filter, with the at least one element being arranged in the at least one column and being configured to steer the particles emanating from the sample to the at least one detection unit.

8. The device of claim 1, wherein the at least one pressure adjustment unit comprises at least one element from the following group: a differentially pumped pressure stage, which is arranged in the at least one column, and at least one stop, which is arranged above the at least one gas line system at the outlet of the focused particle beam from the at least one column.

9. The device of claim 8, wherein, in the beam direction of the particle beam, the at least one differentially pumped pressure stage is arranged in the region of a back-side focal plane of an objective lens in the at least one column.

10. The device of claim 8, further comprising a turbomolecular pump for pumping a vacuum port of a chamber of the at least one differentially pumped pressure stage.

11. The device of claim 8, wherein the chamber of the at least one differentially pumped pressure stage comprises a pressure-type bypass port to the sample chamber for pumping the chamber of the at least one differentially pumped pressure stage.

12. The device of claim 8, wherein, in the beam direction of the particle beam, the at least one differentially pumped pressure stage is arranged upstream of the vacuum pump port of the column.

13. The device of claim 8, wherein the inlet region of the at least one differentially pumped pressure stage comprises a pressure stage tube with a diameter of 1 mm to 3 mm, preferably 1.3 mm to 2.7 mm, more preferably 1.6 mm to 2.4 mm, and most preferably 1.9 mm to 2.1 mm, and with a length ranging from 5 mm to 25 mm, preferably from 7 mm to 18 mm, more preferably from 8 mm to 14 mm, and most preferably from 9 mm to 11 mm.

14. The device of claim 8, wherein the outlet region of the at least one differentially pumped pressure stage comprises a pressure stage tube with a diameter of 2 mm to 4 mm, preferably 2.3 mm to 3.7 mm, more preferably 2.6 mm to 3.4 mm, and most preferably 2.9 mm to 3.1 mm, and with a length ranging from 20 mm to 36 mm, preferably from 23 mm to 33 mm, more preferably from 26 mm to 30 mm, and most preferably from 27 mm to 29 mm.

15. The device of claim 8, wherein the at least one stop has an adjustable aperture.

16. The device of claim 8, wherein the at least one stop comprises at least one piezo actuator which is configured to adjust the aperture.

17. The device of claim 8, further comprising a voltage supply which is configured to apply an electrostatic potential to the at least one stop.

18. The device of claim 8, wherein the aperture of the stop is bigger than a distance of the aperture from a sample surface, preferably bigger by a factor of 1.5, more preferably bigger by a factor of 1.8, and most preferably bigger by a factor of 2.0.

19. The device of claim 15, wherein the aperture comprises a range from 100 μm to 3000 μm, preferably 130 μm to 2000 μm, more preferably 160 μm to 1000 μm and most preferably 200 μm to 600 μm.

20. The device of claim 19, wherein a charge compensating grid has a distance from the sample surface which is half the size of a grid opening of the charge compensating grid.
